(19) United States
(12) Patent Application Publication
(10) Pub. No.: US 2024/0147728 A1
(43) Pub. Date: May 2, 2024

(54) SEMICONDUCTOR MEMORY DEVICE

(71) Applicant: Kioxia Corporation, Tokyo (JP)

(72) Inventors: Toshimitsu IWASAWA, Yokohama Kanagawa (JP); You KAMATA, Yokohama Kanagawa (JP); Sachie FUKUDA, Tokyo (JP); Nobuharu MIYATA, Yokohama Kanagawa (JP); Haruka SHIBAYAMA, Kamakura Kanagawa (JP); Yasumitsu NOZAWA, Yokohama Kanagawa (JP)

(73) Assignee: Kioxia Corporation, Tokyo (JP)

(21) Appl. No.: 18/402,867

(22) Filed: Jan. 3, 2024

Related U.S. Application Data
(63) Continuation of application No. PCT/JP2021/044129, filed on Dec. 1, 2021.

(30) Foreign Application Priority Data
Sep. 16, 2021 (JP) 2021-151468

(51) Int. Cl. H10B 43/40; H10B 41/41

(52) U.S. Cl. CPC H10B 43/40; H10B 41/41

(57) ABSTRACT

According to one embodiment, a semiconductor memory device includes: a plurality of first conductive layers aligned in a first direction with a space in between; a first plug penetrating the first conductive layers; a second conductive layer below the first conductive layers, the second conductive layer being coupled to a lower end of the first plug; a first transistor below the first conductive layers; a second transistor in a second region between the first transistor and a first region below the second conductive layer, the second transistor having a gate electrically coupled to the first transistor and a drain electrically coupled to the first transistor; and a third transistor in the second region, the third transistor having a source and a drain electrically coupled to each other.

### CROSS-REFERENCE TO RELATED APPLICATIONS

This application is a Continuation application of PCT Application No. PCT/JP2021/044129, filed Dec. 1, 2021 and based upon and claiming the benefit of priority from Japanese Patent Application No. 2021-151468, filed Sep. 16, 2021, the entire contents of all of which are incorporated herein by reference.

### FIELD

Embodiments described herein relate generally to a semiconductor memory device.

### BACKGROUND

A NAND flash memory has been known as a semiconductor memory device.

### BRIEF DESCRIPTION OF DRAWINGS

FIG. 1 is a block diagram showing an exemplary configuration of a semiconductor memory device according to the first embodiment.

FIG. 2 is a diagram showing an exemplary circuit configuration of a memory cell array of the semiconductor memory device according to the first embodiment.

FIG. 3 is a diagram schematically showing an exemplary partial structure of the semiconductor memory device according to the first embodiment.

FIG. 4 is a diagram showing an exemplary partial layout of a plug arrangement portion and a diode arrangement portion of the semiconductor memory device according to the first embodiment.

FIG. 5 is a diagram for explaining the layout of a diode arrangement portion of the semiconductor memory device according to the first embodiment in detail.

FIG. 6 is a cross-sectional view showing an exemplary cross-sectional structure of the semiconductor memory device according to the first embodiment.

FIG. 7 is a diagram for explaining a layout of interconnects relating to an antenna element of the semiconductor memory device according to the first embodiment.

FIG. 8 is a diagram for explaining a layout of interconnects relating to another antenna element of the semiconductor memory device according to the first embodiment.

FIG. 9 is a diagram for explaining a layout of a diode arrangement portion of the semiconductor memory device according to a modification example of the first embodiment in detail.

### DETAILED DESCRIPTION

Embodiments will be described below with reference to the drawings. In the description below, structural components having the same function and configuration will be given the same reference symbols. When structural components with a reference symbol in common need to be distinguished from each other, suffixes may be added to the reference symbol. When structural components need not be particularly distinguished, they will be referred to only by the common reference symbol without any suffix.

Functional blocks may be individually executed in the form of hardware, software, or a combination thereof. The functional blocks are not necessarily distinguished from each other as described below. For instance, some of the functions may be executed by functional blocks that differ from the illustrated functional blocks. The illustrated functional blocks may be further divided into smaller functional sub-blocks. The names of the functional blocks and the structural components in the description are given merely for convenience, and are not to restrict the configurations and operations of the functional blocks or structural components.

In general, according to one embodiment, a semiconductor memory device includes: a plurality of first conductive layers aligned in a first direction with a space in between; a first plug penetrating the first conductive layers; a second conductive layer below the first conductive layers, the second conductive layer being coupled to a lower end of the first plug; a first transistor below the first conductive layers; a second transistor in a second region between the first transistor and a first region below the second conductive layer, the second transistor having a gate electrically coupled to the first transistor and a drain electrically coupled to the first transistor; and a third transistor in the second region, the third transistor having a source and a drain electrically coupled to each other.

### First Embodiment

A semiconductor memory device 1 according to the first embodiment will be described below.

### Configuration Example

### (1) Semiconductor Memory Device

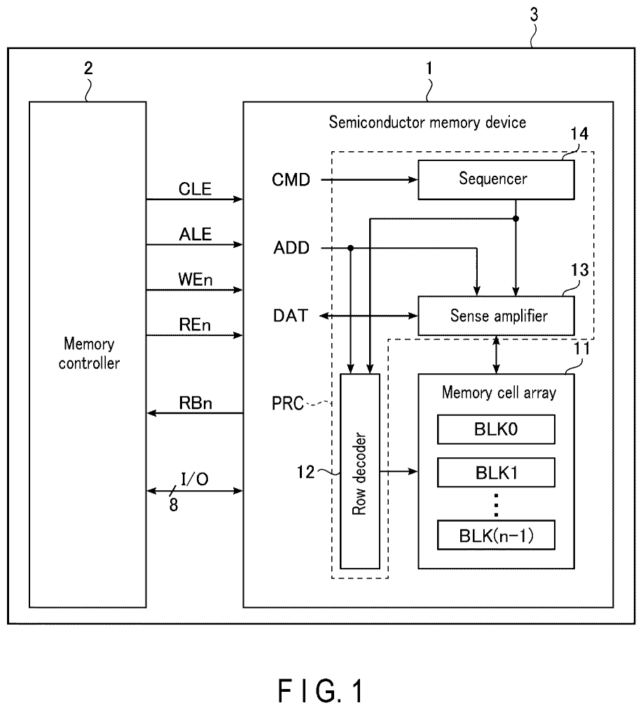

FIG. 1 is a block diagram showing an exemplary configuration of the semiconductor memory device 1 according to the first embodiment. The semiconductor memory device 1 may be a NAND flash memory capable of storing data in a nonvolatile manner, and is controlled by an externally provided memory controller 2. A combination of the semiconductor memory device 1 and the memory controller 2 may constitute a memory system 3, which is a semiconductor memory device. The memory system 3 may be a memory card such as an SD™ card, or a solid state drive (SSD).

Communications conducted between the semiconductor memory device 1 and the memory controller 2 conform to, for example, the NAND interface standard. In the communications between the semiconductor memory device 1 and the memory controller 2, a command latch enable signal CLE, an address latch enable signal ALE, a write enable signal WEn, a read enable signal REn, a ready/busy signal RBn, and an input/output signal I/O may be adopted.

The input/output signal I/O may be an 8-bit signal and may include a command CMD, address information ADD, data DAT, and the like. In the following description, both write data and read data will be denoted with a reference symbol DAT added. The semiconductor memory device 1 receives a command CMD, address information ADD, and write data DAT from the memory controller 2 via the input/output signal I/O.

The command latch enable signal CLE is used for notifying the semiconductor memory device 1 of a period during which the command CMD is transmitted via the signal I/O. The address latch enable signal ALE is used for notifying the semiconductor memory device 1 of a period during which the address information ADD is transmitted via the signal I/O. The write enable signal WEn is used for enabling the semiconductor memory device 1 to input the signal I/O. The read enable signal REn is used for enabling the semiconductor memory device 1 to output the signal I/O. The ready/busy signal RBn is used for notifying the memory controller 2 of whether the semiconductor memory device 1 is in the ready state or the busy state. In the ready state, the semiconductor memory device 1 accepts a command from the memory controller 2. In the busy state, the semiconductor memory device 1 does not receive a command from the memory controller 2 unless it is an exceptional case.

The semiconductor memory device 1 includes a memory cell array 11 and a peripheral circuit PRC. The peripheral circuit PRC includes a row decoder 12, a sense amplifier 13, and a sequencer 14.

The memory cell array 11 includes blocks BLK0 to BLK(n−1) (where n is an integer greater than or equal to 1). A block BLK includes a plurality of nonvolatile memory cells associated with bit lines and word lines, and may be a unit for data erasure.

The sequencer 14 controls the overall operation of the semiconductor memory device 1 based on a received command CMD. For instance, the sequencer 14 controls the row decoder 12, the sense amplifier 13, and the like to execute various operations such as a write operation and a read operation. In a write operation, the received write data DAT is stored in the memory cell array 11. In a read operation, the read data DAT is read from the memory cell array 11.

The row decoder 12 selects, based on the received address information ADD, a target block BLK upon which an operation such as a read operation or a write operation is to be executed. The row decoder 12 transfers a voltage to the word line associated with the selected block BLK.

The sense amplifier 13 executes a transfer operation of the data DAT between the memory controller 2 and the memory cell array 11 based on the received address information ADD. That is, in a write operation, the sense amplifier 13 holds the received write data DAT and applies a voltage to a bit line based on the write data DAT. In a read operation, the sense amplifier 13 applies a voltage to the bit line to read the data stored in the memory cell array 11 as read data DAT, and outputs the read data DAT to the memory controller 2.

### (2) Memory Cell Array

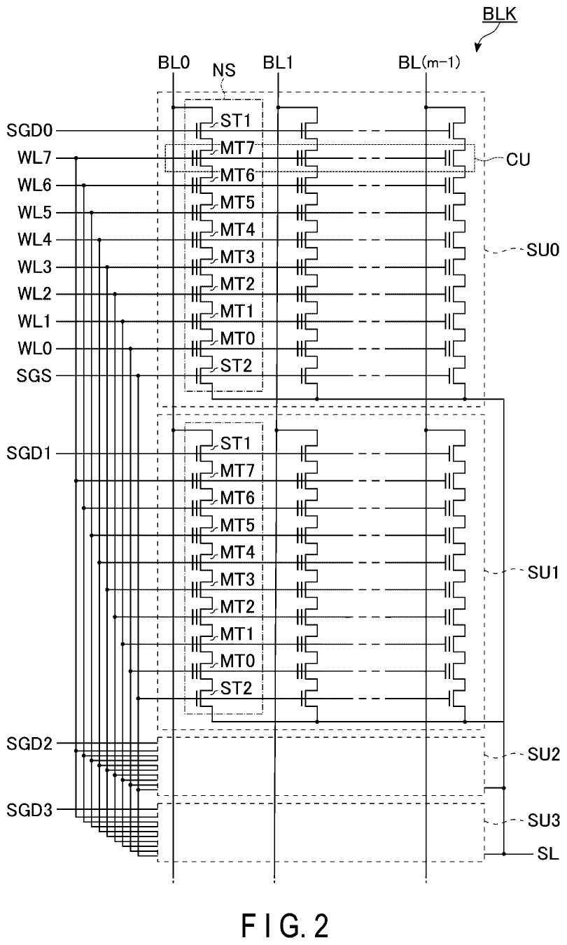

FIG. 2 shows an exemplary circuit configuration of a memory cell array 11 of the semiconductor memory device 1 according to the first embodiment. As an example of the circuit configuration of the memory cell array 11, an exemplary circuit configuration of a block BLK of the memory cell array 11 is illustrated. Other blocks BLK of the memory cell array 11 may respectively have a circuit configuration similar to that of FIG. 2.

The block BLK includes, for example, four string units SU0 to SU3. Each of the string units SU includes a plurality of NAND strings NS. The NAND strings NS are associated with m bit lines BL0 to BL(m−1) (where m is an integer greater than or equal to 1) on a one-to-one basis. Each of the NAND strings NS is coupled to a corresponding bit line BL, and includes, for example, memory cell transistors MT0 to MT7 and select transistors ST1 and ST2. Each of the memory cell transistors MT includes a control gate (hereinafter also referred to as a “gate”) and a charge storage layer, and stores data in a nonvolatile manner. The select transistors ST1 and ST2 are each used in various operations to select the NAND string NS that includes these select transistors ST1 and ST2.

The drain of the select transistor ST1 of each NAND string NS is coupled to the bit line BL associated with the NAND string NS. The memory cell transistors MT0 to MT7 are coupled in series between the source of the select transistor ST1 and the drain of the select transistor ST2. The source of the select transistor ST2 is coupled to a source line SL.

The select transistors ST1 and ST2, the memory cell transistors MT0 to MT7, and interconnects coupled to the gates of these transistors will be described using an integer j and an integer k. In the example of FIG. 2, the following description applies to each of the cases where j is any integer from 0 to 3 and cases where k is any integer from 0 to 7.

The gates of the select transistors ST1 of the NAND strings NS included in a string unit SUj are commonly coupled to a select gate line SGDj. The gates of the select transistors ST2 of the NAND strings NS included in the block BLK are commonly coupled to the select gate line SGS. The gates of the memory cell transistors MTk of the NAND strings NS included in the block BLK are commonly coupled to the word line WLk.

Each bit line BL is coupled to the drains of the select transistors ST1 of the associated NAND strings NS included in the respective string units SU of the block BLK. The source line SL is commonly coupled to the sources of the select transistors ST2 of the NAND strings NS included in the block BLK, and thus is shared between the string units SU of the block BLK. The source line SL is coupled in the same manner, for example, in other blocks BLK and thereby shared between the blocks BLK.

A set of memory cell transistors MT commonly coupled to one word line WL in one string unit SU may be referred to as a “cell unit CU”. For instance, a set of one-bit data items of the same order retained in each of the memory cell transistors MT in the cell unit CU may be referred to as “one-page data”. If data of multiple bits is retained in each memory cell by the MLC method or the like, multiple items of such “one-page data” may be retained in one cell unit CU.

The circuit configuration of the memory cell array 11 has been described above. The circuit configuration of the memory cell array 11, however, is not limited to the above description. For instance, the number of string units SU included in each block BLK may be freely determined. Furthermore, the number of memory cell transistors MT, the number of select transistors ST1, and the number of select transistors ST2 included in each NAND string NS may also be freely determined. The number of word lines WL, the number of select gate lines SGD, and the number of select gate lines SGS will be changed in accordance with the number of memory cell transistors MT, the number of select transistors ST1, and the number of select transistors ST2 in each NAND string NS.

### (3) Structure of Semiconductor Memory Device

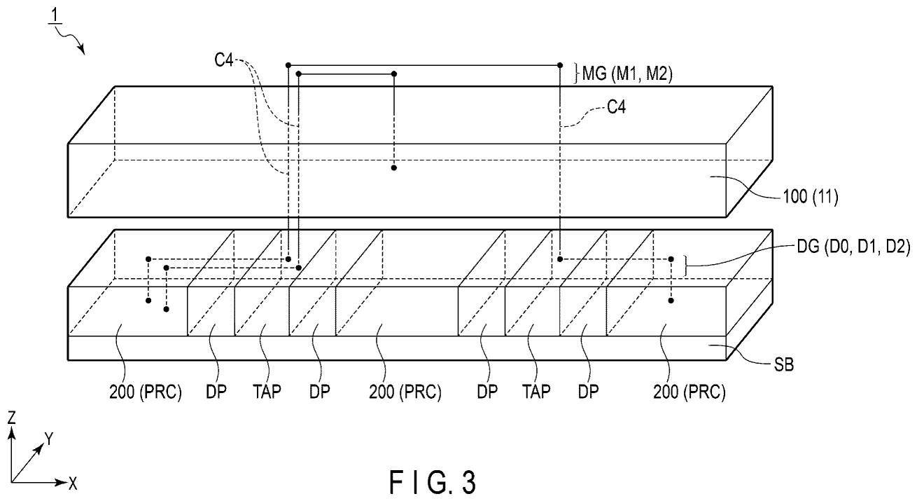

FIG. 3 schematically illustrates an exemplary partial structure of the semiconductor memory device 1 according to the first embodiment.

The semiconductor memory device 1 includes a semiconductor substrate SB. For convenience of reference, directions are defined below based on the semiconductor substrate SB. Two directions orthogonal to each other and both parallel to a surface of the semiconductor substrate SB are defined as an X direction and a Y direction. A direction intersecting this surface and extending from the surface toward a side on which the memory cell array 11 is formed is defined as a Z direction. The Z direction is described as being orthogonal to the X direction and the Y direction, but is not necessarily limited thereto. In the following description, the Z direction is referred to as “upward” and the direction opposite to the Z direction is referred to as “downward”. Such notation is merely for convenience and is irrelevant to, for example, the direction of gravity.

The semiconductor memory device 1 includes a memory cell portion 100 above the semiconductor substrate SB. A memory cell array 11 is provided in the memory cell portion 100. Specifically, the memory cell transistors MT shown in FIG. 2 are three-dimensionally arranged in this memory cell portion 100.

The semiconductor memory device 1 further includes a peripheral circuit portion 200, a plug arrangement portion TAP, and a diode arrangement portion DP between the semiconductor substrate SB and the memory cell portion 100.

In the example of FIG. 3, the plug arrangement portions TAP and the peripheral circuit portions 200 are alternately and sequentially provided at spacings along the X direction. For each set of one plug arrangement portion TAP and one peripheral circuit portion 200, one diode arrangement portion DP may be provided between the plug arrangement portion TAP and the peripheral circuit portion 200.

In each peripheral circuit portion 200, peripheral circuit elements are provided on the semiconductor substrate SB to constitute a peripheral circuit PRC. A peripheral circuit element provided in a peripheral circuit portion 200 is electrically coupled to another structural element, for example, via interconnects in a metal interconnect layer group DG and a metal interconnect layer group MG. Details will be provided below.

The peripheral circuit element is electrically coupled below the memory cell portion 100 to a contact plug C4 provided in a plug arrangement portion TAP via interconnects in the metal interconnect layer group DG. The contact plug C4 may extend upward above the memory cell portion 100. Via this contact plug C4, the peripheral circuit element is further electrically coupled to an interconnect in the metal interconnect layer group MG above the memory cell portion 100. For instance, with the interconnect electrically coupled to the memory cell portion 100, an access from the peripheral circuit PRC to the memory cell array 11 can be realized as described with reference to FIG. 1. Alternatively, with this interconnect electrically coupled to an interconnect in the metal interconnect layer group DG via another contact plug C4 provided in another plug arrangement portion TAP, the peripheral circuit element may be electrically coupled to another peripheral circuit element provided in another peripheral circuit portion 200. In this manner, two peripheral circuit elements can be electrically coupled to each other via the interconnects in the metal interconnect layer group MG in addition to the interconnects in the metal interconnect layer group DG.

The contact plugs extending from below the memory cell portion 100 upward above the memory cell portion 100 as is the above described contact plug C4 are collectively referred to as contact plugs C4. A contact plug C4 is provided in the plug arrangement portion TAP and is not provided, for example, in the peripheral circuit portion 200 or the diode arrangement portion DP.

Here, plasma is generated, for example, at an etching step during the manufacture of the semiconductor memory device 1, as a result of which charges may be accumulated in the interconnects of the metal interconnect layer group DG that are relatively close to the semiconductor substrate SB. This may cause a voltage higher than the designed voltage of a metal-oxide semiconductor (MOS) transistor to be applied via these interconnects to the gate of the MOS transistor, which serves as a peripheral circuit element arranged in a peripheral circuit portion 200. The gate insulator between the gate and the semiconductor substrate SB may thereby be damaged, changing the characteristics of the transistor. Hereinafter, such a characteristic variation will be referred to as an “antenna violation”.

A plurality of n-channel MOS transistors, which may be used as a countermeasure against the antenna violation, are provided in each of the diode arrangement portions DP. Such MOS transistors may be referred to as antenna elements. Among the antenna elements, the gate and drain regions of the antenna elements used as a countermeasure against antenna violation are each electrically coupled to an interconnect in the metal interconnect layer group DG. That is, the antenna element may be diode-coupled by the interconnect, and the diode-coupled antenna element is coupled to the interconnect. In this specification, the diode arrangement portion DP may also be referred to as an antenna element arrangement portion DP.

FIG. 3 shows a metal interconnect layer group DG including metal interconnect layers D0, D1 and D2, and a metal interconnect layer group MG including metal interconnect layers M1 and M2. These metal interconnect layers will be described in detail with reference to other drawings. A metal interconnect layer group DG is described as including three metal interconnect layers and a metal interconnect layer group MG is described as including two metal interconnect layers in the present specification. The number of metal interconnect layers included in these metal interconnect layer groups, however, is not necessarily limited thereto.

Among the plug arrangement portions TAP and the diode arrangement portions DP described with reference to FIG. 3, a plug arrangement portion TAP and a diode arrangement portion DP provided adjacent to each other in the X direction, for example, will be focused on in the description below. The same description applies to other pairs of a plug arrangement portion TAP and a diode arrangement portion DP provided adjacent to each other.

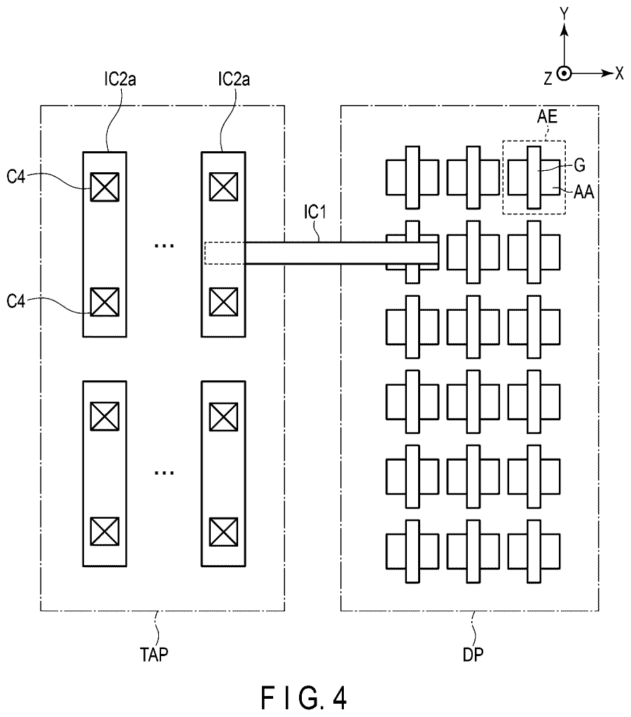

FIG. 4 illustrates an exemplary partial layout of a plug arrangement portion TAP and a diode arrangement portion DP of the semiconductor memory device 1 according to the first embodiment. The layout of FIG. 4 is presented merely as an example, and the layout of the plug arrangement portion TAP and the diode arrangement portion DP is not limited to the illustrated one.

First, the plug arrangement portion TAP will be described.

In the plug arrangement portion TAP, for example, a plurality of interconnects IC2a extending in the Y direction are provided. A contact plug C4 may be provided on each of the interconnects IC2a. The example shown in FIG. 4 will be described below. Hereinafter, interconnects in a metal interconnect layer, which are provided in the plug arrangement portion TAP and can be coupled to the contact plugs C4, are collectively referred to as interconnects IC2a.

In the example of FIG. 4, two contact plugs C4 are provided on one interconnect IC2a extending in the Y direction. The two contact plugs C4 are provided adjacent to each other, for example, with a spacing in the Y direction. A plurality of such interconnects IC2a are sequentially provided adjacent to each other, for example, at spacings in the X direction. Further, in the example of FIG. 4, two sets of such interconnects IC2a are provided adjacent to each other with a spacing in the Y direction, for example.

Next, a diode arrangement portion DP will be described.

A plurality of antenna elements AE are provided in the diode arrangement portion DP. In the example of FIG. 4, antenna elements AE are sequentially provided adjacent to each other, for example, in the X direction. Plural sets of such antenna elements AE are repeatedly provided so as to be adjacent to each other, for example, in the Y direction. That is, the antenna elements AE are arranged in a regular manner in the diode arrangement portion DP.

The configuration of the antenna element AE will be described by taking one antenna element AE as an example. The same configuration may apply to other antenna elements AE.

The antenna element AE includes a pair of source and drain regions (not shown) and a gate electrode G. The pair of source and drain regions is provided on the surface of the active area AA of the semiconductor substrate SB, for example, along the X direction with a spacing. The gate electrode G is provided on the upper surface of the active area AA between the source region and the drain region with a gate insulator (not shown) interposed.

The gate electrode G and the drain region of an antenna element AE are electrically coupled to an interconnect IC1. That is, the antenna element AE is diode-coupled, for example, by the interconnect IC1, and the diode-coupled antenna element AE is coupled to the interconnect IC1. The interconnect IC1 extends, for example, in the X direction. The interconnect IC1 is positioned above the antenna element AE and below the interconnect IC2a. The interconnect IC1 is electrically coupled to, for example, an interconnect IC2a. In the following description, any interconnect extending, for example, in the X-direction in a metal interconnect layer below the interconnects IC2a and coupled to one of the interconnects IC2a will be referred to as an interconnect IC1.

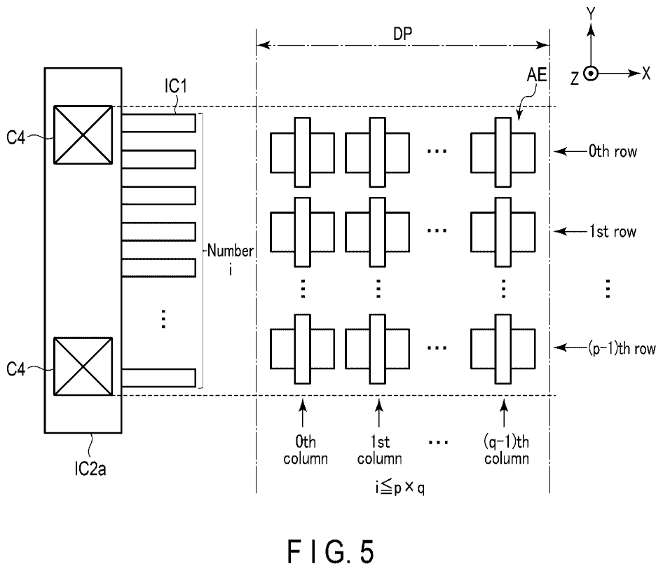

FIG. 5 is a diagram for describing the layout of a diode arrangement portion DP of the semiconductor memory device 1 according to the first embodiment in detail.

In the plug arrangement portion TAP, contact plugs C4 are provided, for example, sequentially adjacent to each other at spacings along the Y direction. A spacing between any two contact plugs C4 adjacent to each other in the Y direction may be substantially constant. The term “substantially” is used here with the intention that a margin of error within a design range should be allowed. For instance, four contact plugs C4 on the two interconnects IC2a arranged in the Y direction as illustrated in FIG. 4 are provided sequentially adjacent to each other at equal spacings along the Y direction. FIG. 5 shows two contact plugs C4 (hereinafter referred to as a “first contact plug” and a “second contact plug”) adjacent to each other on an interconnect IC2a.

A region whose position in the Y direction is defined between one end of the first contact plug C4 on the opposite side with respect to the second contact plug C4 and one end of the second contact plug C4 on the opposite side with respect to the first contact plug C4 may be referred to as an inter-C4 plug region.

In the semiconductor memory device 1, the number of interconnects IC1 provided in the inter-C4 plug region may reach up to i (where i is an integer greater than or equal to 1). The number i is determined, for example, in accordance with the design of the semiconductor memory device 1.

The portion of the diode arrangement portion DP included in the inter-C4 plug region may be referred to as an “inter-C4 plug diode region”. In the inter-C4 plug diode region, antenna elements AE are aligned as follows.

For example, the number q of antenna elements AE are arranged adjacent to each other along the X direction, thereby forming a set. The spacing between any two adjacent antenna elements AE of the set may be substantially constant. Further, p sets each including q antenna elements AE are repeatedly provided sequentially adjacent to each other, for example in the Y direction. The spacing between any two adjacent sets may be substantially constant. That is, for example, when an alignment of antenna elements AE in the X direction is regarded as one row and an alignment of antenna elements AE in the Y direction is regarded as one column, p×q antenna elements AE are arranged to form p rows and q columns, where p and q are each integers that satisfy the condition that p×q is greater than or equal to i, for example. The purpose of this is to enable each of the number i of interconnects IC1 to be coupled to one of the antenna elements AE, for example. For example, when i is 7, each of p and q may be 3.

In the above description, the arrangement of antenna elements AE according to the inter-C4 plug region has been described. Such an arrangement of antenna elements AE may be repeated for every two contact plugs C4 adjacent to each other in the Y direction. Alternatively, such an arrangement of antenna elements AE may be repeated for each interconnect IC2a in which two contact plugs C4 are provided.

In addition, the arrangement of antenna elements AE corresponding to the inter-C4 plug region has been described above. The arrangement of antenna elements AE corresponding to a region whose position in the Y direction is defined to be between the center of the first contact plug C4 and the center of the second contact plug C4 can be described in the same manner. Alternatively, the arrangement of antenna elements AE corresponding to a region whose position in the Y direction is defined to be between the two end surfaces of the interconnect IC2a in the Y direction can be described in the same manner.

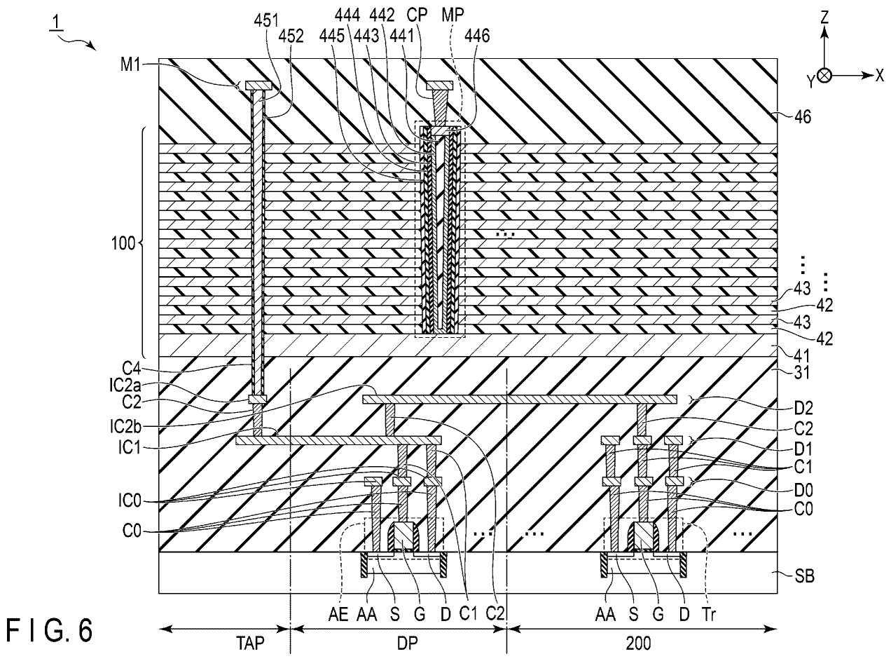

FIG. 6 is a cross-sectional view showing an exemplary cross-sectional structure of the semiconductor memory device 1 according to the first embodiment. The cross-sectional view shown in FIG. 6 shows the semiconductor memory device 1 cut along a plane perpendicular to the Y direction.

An antenna element AE and a MOS transistor Tr are provided on the upper surface of the semiconductor substrate SB. The transistor Tr corresponds to the MOS transistor provided in the peripheral circuit portion 200 described with reference to FIG. 3. The structure of the antenna element AE will be described in further detail. The transistor Tr has the same structure as that of the antenna element AE.

An active area AA is provided in a region of the semiconductor substrate SB. The active area AA reaches the upper surface of the semiconductor substrate SB. The antenna element AE includes a pair of a source region S and a drain region D provided on the surface of the active area AA, a gate insulator between the source region S and the drain region D on the upper surface of the active area AA, and a gate electrode G on the upper surface of the gate insulator.

The metal interconnect layers D0, D1, and D2 shown in FIG. 3 are provided above the transistors Tr and the antenna elements AE. Each of the metal interconnect layers includes a plurality of mutually insulated interconnects. The same applies to other metal interconnect layers to be described below. By way of such interconnects, the source, drain, and gate of each transistor can be electrically coupled to other structural components, as will be described below.

A contact plug C0 is provided on the upper surface of the gate electrode G of the transistor Tr. The upper surface of the contact plug C0 is in contact with an interconnect in the metal interconnect layer D0. A contact plug C1 may be provided on the upper surface of this interconnect. The upper surface of the contact plug C1 is in contact with an interconnect in the metal interconnect layer D1. A contact plug C2 may be provided on the upper surface of this interconnect. The upper surface of the contact plug C2 is in contact with an interconnect IC2b in the metal interconnect layer D2. The interconnect IC2b extends, for example, in the X direction. The interconnect IC2b extends, for example, to the diode arrangement portion DP where the antenna element AE is provided. The interconnect IC2b may extend up to a position above the antenna element AE.

The interconnect IC2b is electrically coupled, for example, to a contact plug C4 provided in the plug arrangement portion TAP. Details will be described below.

The interconnect IC2b is in contact with the upper surface of a contact plug C2 arranged closer to the contact plug C4 than the above described contact plug C2. The contact plug C2 is provided on the upper surface of an interconnect IC1 in the metal interconnect layer D1. The interconnect IC1 extends, for example, in the X direction. Another contact plug C2 is provided on the upper surface of the interconnect IC1. The upper surface of this contact plug C2 is in contact with an interconnect IC2a in the metal interconnect layer D2. The interconnect IC2a extends, for example, in the Y direction. The contact plug C4 is provided on the upper surface of the interconnect IC2a. As described above, the interconnect IC2b is coupled to the interconnect IC2a extending in the metal interconnect layer D2 in the same manner as the interconnect IC2b, via the interconnect IC1 in another metal interconnect layer D1, and is thereby electrically coupled to the contact plug C4 on the interconnect IC2a.

The diode-coupled antenna element AE is coupled to this interconnect IC1. More specifically, the drain region D and the gate electrode G of the antenna element AE are electrically coupled respectively to the interconnect IC1 via interconnects in the metal interconnect layer D0 and various contact plugs. In the example of FIG. 6, contact plugs C0 are provided on the upper surface of the drain region D, the upper surfaces of the contact plugs C0 are in contact with the interconnects IC0 in the metal interconnect layer D0, the contact plugs C1 are provided on the upper surface of the interconnect IC0, and the contact plugs C1 are in contact with the interconnect IC1. The same applies to the electrical coupling between the gate electrodes G and the interconnect IC1. The drain region D and the gate electrode G may be coupled to the same interconnect IC0, and the interconnect IC0 may be coupled to the interconnect IC1 via a contact plug C1. The interconnects in the metal interconnect layer D0 will be collectively referred to as interconnects IC0 below.

The above-described connection via the interconnects in the metal interconnect layers D0, D1, and D2 is merely discussed as an example. Various contact plugs and interconnects in the metal interconnect layers DO, D1, and D2 other than the ones described above are also provided. For convenience of reference, FIG. 6 may not show all of the contact plugs or interconnects present in metal interconnect layers D0, D1, and D2.

The memory cell portion 100 is provided above the metal interconnect layer D2. In the memory cell portion 100, part of the structure of the memory cell array 11 is configured by a stack including insulators 42 and conductors 43 and a memory pillar MP in the stack. The structure of the memory cell portion 100 will be described below.

A conductor 41 is provided above the metal interconnect layer D2. The conductor 41 functions as the source line SL. The insulators 42 and the conductors 43 are alternately stacked on the upper surface of the conductor 41. In the example of FIG. 6, the insulator 42 and the conductor 43 are alternately stacked in this order on the upper surface of the conductor 41 and repeated ten times. Each of the conductors 43 functions as part of one of the word lines WL and the select gate lines SGD and SGS.

A memory pillar MP is provided in the stack of the insulators 42 and the conductors 43. The memory pillar MP extends, for example, in the Z direction. The upper end of the memory pillar MP is positioned above the uppermost conductor 43, and the lower end of the memory pillar MP reaches the conductor 41.

The memory pillar MP includes, for example, an insulator 441, a semiconductor 442, a tunnel insulating film 443, a charge storage film 444, a block insulating film 445, and a semiconductor 446. Details will be described below. The upper end of the pillar-shaped insulator 441 is positioned above the upper surface of the uppermost conductor 43, and the lower end of the insulator 441 is positioned below the lower surface of the lowermost conductor 43. The side surface and lower surface of the insulator 441 are covered with the semiconductor 442. The lower end of the semiconductor 442 is in contact with the conductor 41. The semiconductor 446 may be provided in contact with the upper ends of the insulator 441 and the semiconductor 442. The tunnel insulating film 443, the charge storage film 444, and the block insulating film 445 may be sequentially provided in this order on the side surfaces of the semiconductor 442 and the semiconductor 446.

Each of the portions of the memory pillar MP that intersect the conductors 43 functions as one of memory cell transistors MT and select transistors ST.

A contact plug CP is provided on the upper surface of the semiconductor 446. The upper surface of the contact plug CP is in contact with an interconnect in the metal interconnect layer M1 shown in FIG. 3.

The above-mentioned contact plug C4 extends, for example, in the Z direction, and is provided in the conductor 41, the insulators 42, and the conductors 43. The upper end of the contact plug C4 is positioned above the uppermost conductor 43. The contact plug C4 may include a conductor 451 and an insulating film 452. The insulating film 452 is provided on the side surface of the pillar-shaped conductor 451. The conductor 451 is insulated from the conductors 41 and 43 by the insulating film 452. The upper surface of the conductor 451 is in contact, for example, with an interconnect in the metal interconnect layer M1. FIG. 6 illustrates an example of the contact plug C4 and the interconnect in contact with each other. The contact plug C4 and the interconnect, however, may be electrically coupled to each other by way of another interconnect and/or another contact plug.

An insulator 31 is provided in a portion between the substrate SB and the conductor 41, where the transistors Tr, antenna elements AE, contact plugs, and interconnects of the metal interconnect layers D0, D1, and D2, are not provided.

Furthermore, an insulator 46 is provided in a portion above the uppermost conductor 43 where the memory pillar MP, the contact plugs, and the interconnects of the metal interconnect layers are not provided.

In the example of FIG. 6, the antenna element AE diode-coupled to the interconnect IC1 is shown. All of the antenna elements AE described with reference to FIGS. 4 and 5, however, may not necessarily establish the connection relationship as shown in FIG. 6.

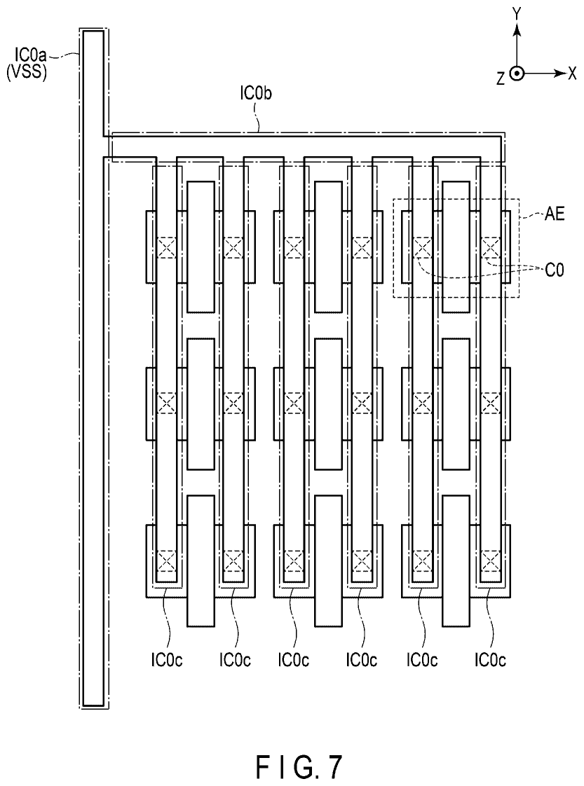

FIG. 7 is a diagram for explaining the layout of the interconnects relating to antenna elements AE of the semiconductor memory device 1 according to the first embodiment, which do not establish the connection relationship as shown in FIG. 6. For convenience of reference, FIG. 7 may not show all of the actually provided interconnects.

In the metal interconnect layer D0, an interconnect IC0a extending, for example, in the Y direction is provided. A voltage VSS is applied to the interconnect IC0a. The voltage VSS is a reference voltage such as a ground voltage.

In the metal interconnect layer D0, an interconnect IC0b extending, for example, in the X direction is provided. For convenience of reference, the interconnect IC0a and the interconnect IC0b are distinguished from each other, but these two interconnects are formed as one body.

In the metal interconnect layer D0, a plurality of interconnects IC0c extending, for example, in the Y direction is provided. To be more specific, two interconnects IC0c are provided above each set of antenna elements AE aligned in the Y direction. The two interconnects IC0c are provided respectively above the source region S and drain region D of each of the antenna elements AE in the set. The source region S and the drain region D of each antenna element AE are coupled to the two interconnects IC0c via contact plugs C0. Although the interconnect IC0b and the interconnects IC0c are distinguished from each other for ease of reference, the interconnect IC0b and the interconnects IC0c are formed as one body.

With such a connection relationship, the voltage VSS is applied to the source region S and the drain region D of the antenna elements AE which are not in the connection relationship as shown in FIG. 6.

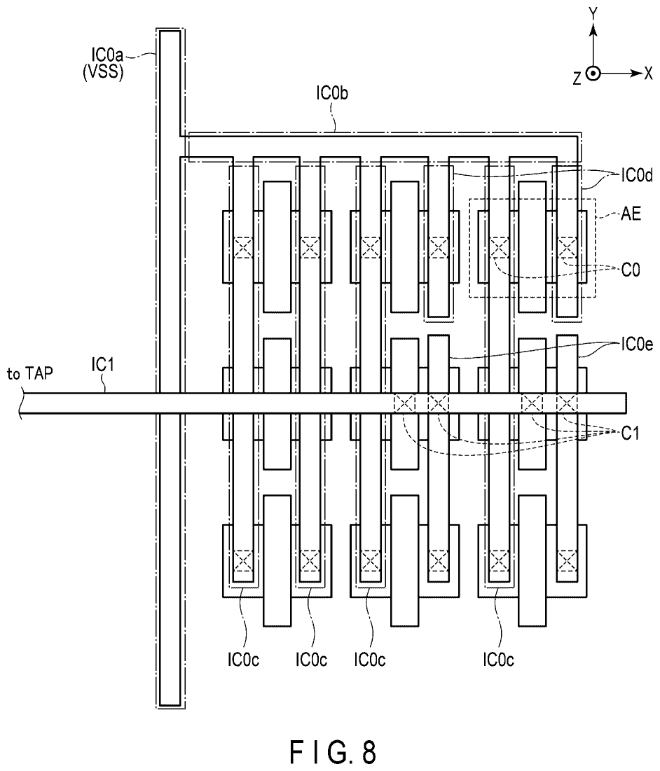

FIG. 8 is a diagram for explaining the layout of interconnects relating to the antenna elements AE establishing the connection relationship as shown in FIG. 6 in the semiconductor memory device 1 according to the first embodiment. For convenience of reference, FIG. 8 may not show all of the actually provided interconnects.

FIG. 8 includes the interconnect IC0a that has been described with reference to FIG. 7. In addition, the interconnect IC0b and interconnects IC0c similar to those described with reference to FIG. 7 are provided.

In place of some of the interconnects IC0c shown in FIG. 7, a set of an interconnect IC0d and an interconnect IC0e is provided in the metal interconnect layer D0. Each of the interconnect IC0d and the interconnect IC0e extends, for example, in the Y direction. The interconnect IC0d and the interconnect IC0e each correspond to a configuration of an interconnect IC0c of FIG. 7 that has been divided. The interconnects IC0d are integrally formed with the interconnect IC0b, and the end surfaces of the interconnects IC0d face the end surfaces of the interconnects IC0e. The interconnects IC0e are not electrically coupled to the interconnects IC0d, and therefore are not electrically coupled to the interconnect IC0a, either.

The interconnect IC0e is coupled to the drain region D of an antenna element AE via a contact plug C0 in the same manner as the interconnect IC0c described with reference to FIG. 7. The interconnect IC0e is coupled to an interconnect IC1 via a contact plug C1. Similarly, the gate electrode G of the antenna element AE is also electrically coupled to the interconnect IC1.

With such a connection relationship, the antenna elements AE are diode-coupled and coupled to the interconnect IC1 as a countermeasure against antenna violation. FIG. 8 shows two antenna elements AE coupled in this manner.

FIG. 8 shows a configuration in which the interconnects IC0c of FIG. 7 are divided. The present embodiment is not limited thereto, however. The memory device 1 may have a configuration in which the interconnect IC0b is divided instead of the interconnects IC0c. Further, as described with reference to FIG. 6, when the drain regions D and the gate electrodes G of the respective antenna elements AE are coupled to the same interconnect IC0 in the metal interconnect layer D0, the antenna element AE having electrical coupling to the interconnect IC1 as a countermeasure against the antenna violation may be coupled to the interconnect IC1 via a single contact plug C1.

### Advantageous Effects

The semiconductor memory device 1 according the first embodiment produces effects as described below.

In the semiconductor memory device 1, the gate electrode G of the transistor Tr provided in a peripheral circuit portion 200 may be electrically coupled to the transistor Tr provided in another peripheral circuit portion 200 via interconnects in the metal interconnect layer group MG in addition to the interconnects in the metal interconnect layer group DG. By use of such interconnects of the metal interconnect layer group MG, the volume of the interconnects for electrical coupling in the metal interconnect layer group DG, which is relatively close to the semiconductor substrate SB, can be reduced. This can also reduce electric charges that tend to be accumulated in the interconnects in the metal interconnect layer group DG in the vicinity of the semiconductor substrate SB when plasma is generated at a certain step in the manufacture of the semiconductor memory device 1. That is, countermeasures may be implemented against antenna violation.

In the above-described electrical coupling using the interconnects in the metal interconnect layer group DG and the metal interconnect layer group MG, a contact plug C4 is adopted. This contact plug C4 is provided in the plug arrangement portion TAP but not, for example, in the peripheral circuit portion 200. That is, the region in which the contact plug C4 can be arranged is limited. For this reason, in the electrical coupling, the interconnects in the metal interconnect layer group DG are used for connection from the gate electrode G of the transistor Tr to the contact plug C4. If the interconnects in the metal interconnect layer group DG have a large volume, the use of the interconnects in the metal interconnect layer group MG as described above may not be sufficient to realize the countermeasures against the antenna violation.

The semiconductor memory device 1 includes a diode arrangement portion DP provided adjacent to the plug arrangement portion TAP. This diode arrangement portion DP is provided with a plurality of antenna elements AE. As described with reference to FIG. 6, at least one diode-coupled antenna element AE is coupled, for example, to the interconnect IC1 of the metal interconnect layer group DG interposed between the gate electrode G of the transistor Tr and the contact plug C4. An antenna element AE coupled in this manner is designed such that, when the voltages of the interconnects of the metal interconnect layer group DG that are electrically coupled to the antenna element AE are increased, the electric charges accumulated in these interconnects can be lowered via the antenna element AE. That is, an antenna element AE used in this manner implements a countermeasure against antenna violation. The semiconductor memory device 1 according to the first embodiment adopts the antenna element AE provided in the diode arrangement portion DP as a countermeasure against the antenna violation, which can suppress the characteristic variations of the peripheral circuit element in the manufacturing process of the semiconductor memory device 1.

The semiconductor memory device 1 is provided with a diode arrangement portion DP between a plug arrangement portion TAP and a peripheral circuit portion 200. This diode arrangement portion DP can be provided without increasing the chip area for the reason described below.

The interconnect IC1 of the metal interconnect layer D1 is used, as discussed with reference to FIGS. 4 and 6, for coupling the interconnect IC2a extending, for example, in the Y direction in the metal interconnect layer D2 in the plug arrangement portion TAP to the interconnect IC2b extending, for example, in the X direction in the metal interconnect layer D2 and coupled to the transistor Tr of the peripheral circuit portion 200. That is, a region for coupling via the interconnect IC1 is provided between the plug arrangement unit TAP and the peripheral circuit portion 200. In general, no element is provided in this region. The diode arrangement portion DP may be considered to correspond to such a region in which an antenna element AE is provided. As a result, the semiconductor memory device 1 realizes a diode arrangement portion DP without increasing its chip area. In addition, the antenna elements AE in such a diode arrangement portion DP can be easily connected to the interconnect IC1 as a countermeasure against antenna violation.

The semiconductor memory device 1 according to the first embodiment further offers the following effects.

As described with reference to FIG. 7, for example, interconnects IC0 and contact plugs C0 for the antenna elements AE are provided in the diode arrangement portion DP of the semiconductor memory device 1. This makes it easy to deal with antenna violation when the antenna violation occurs in the interconnects of the metal interconnect layer group DG electrically coupled to the gate electrode G of a transistor Tr in the semiconductor memory device 1. Details are described below.

In a next production of the memory devices 1, the interconnect IC1 of the interconnect layer group DG relating to the antenna violation is coupled to the antenna elements AE below this interconnect IC1 in the manner as described with reference to FIG. 8. This can be easily realized, for example, by dividing the interconnect IC0c into the interconnect IC0d and the interconnect IC0e so as to arrange contact plugs C1. Thus, improvements can be easily made to the semiconductor memory devices 1 according to the first embodiment so as to deal with an antenna violation even that is later discovered to have occurred.

As described with reference to FIG. 4, the source region S, the drain region D, and the gate electrode G of the antenna element AE are aligned, for example, in the X direction. As a result, the coupling of the antenna elements AE to the interconnect IC1 extending in the X direction in a manner as described above can be further facilitated.

### Modification Examples

The structure of the semiconductor memory device 1 is not limited to those described with reference to FIGS. 3 to 8. Another example will be described below. In this description, differences with respect to those described by referring to FIGS. 3 to 8 will be mainly focused on. The semiconductor memory device 1 according to a modification example of the first embodiment described below can also produce the same effects as those discussed above.

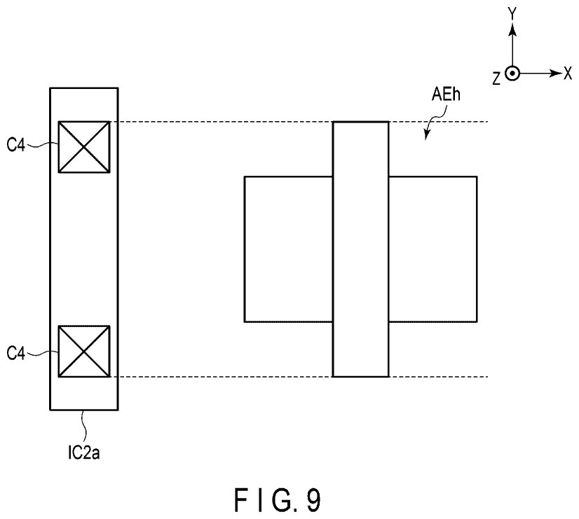

FIG. 9 is a diagram for explaining in detail the layout of a diode arrangement portion DP in the semiconductor memory device 1 according to the modification example of the first embodiment. The description will be given by focusing on an inter-C4 plug diode region for a set of two contact plugs C4 (hereinafter referred to as the “first contact plug” and “second contact plug”) arranged adjacent to each other in the Y directions in the same manner as in the example of FIG. 5.

In the inter-C4 plug diode region, for example, at least one high-voltage antenna element AEh is provided. This antenna element AEh may be used as a countermeasure against antenna violation relating to the interconnects IC1 that are adopted for transfer of high-voltage signals. The alignment of such an antenna element AEh may be repeated for every two contact plugs C4 adjacent to each other in the Y direction. Alternatively, the alignment of such an antenna element AEh may be repeated for every interconnect IC2a in which two contact plugs C4 are provided.

In the inter-C4 plug diode region, high voltage signals of only a single type, for example, are transferred. In such a situation, the antenna elements AEh provided as described above can realize the countermeasures against the antenna violation relating to the interconnect IC1 used for the transfer of high-voltage signals.

In the above description, the arrangement of the antenna element AEh corresponding to the inter-C4 plug region has been described. The arrangement of an antenna element AEh corresponding to a region whose position in the Y direction is between the center of the first contact plug C4 and the center of the second contact plug C4 can be explained in the same manner. Alternatively, the arrangement of an antenna element AEh corresponding to a region whose position in the Y direction is between the two end surfaces of the interconnect IC2a in the Y direction can also be explained in the same manner.

### Other Embodiments

In the above description, an example adopting a diode-coupled MOS transistor as a diode for a countermeasure against antenna violation has been described. The diode used as a countermeasure against the antenna violation, however, is not limited thereto. For example, a PN junction diode may be adopted.

In the above description, an example in which a diode-coupled antenna element is coupled to a certain interconnect, and the certain interconnect is electrically coupled to an interconnect in the metal interconnect layer group above the memory cell portion via a contact plug, has be described. The interconnect to which the diode-coupled antenna element is coupled, however, may not necessarily be electrically coupled to an interconnect in the metal interconnect layer group above the memory cell portion.

Throughout this specification, “coupling” refers to electrical connection, and the coupling does not exclude coupling with another component interposed.

In this specification, expressions such as “same”, “equal”, “constant”, and “maintained” are intended to include a case where there is some error within a design range when the technique described in the embodiment is actually performed. The same applies to a case where the term “substantially” is used together with these expressions, such as “substantially the same”. In addition, the expression “applying/supplying a certain voltage” is intended to mean both that control is performed so as to apply or supply this voltage and that the voltage is actually applied or supplied. Application or supply of a voltage may include application or supply of 0 volts.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first conductive layers aligned in a first direction with a space in between;
a first plug penetrating the first conductive layers;
a second conductive layer below the first conductive layers, the second conductive layer being coupled to a lower end of the first plug;
a first transistor below the first conductive layers;
a second transistor in a second region between the first transistor and a first region below the second conductive layer, the second transistor having a gate electrically coupled to the first transistor and a drain electrically coupled to the first transistor; and
a third transistor in the second region, the third transistor having a source and a drain electrically coupled to each other.

2. The semiconductor memory device according to claim 1, wherein
the first transistor is electrically coupled to the first plug.

3. The semiconductor memory device according to claim 1, wherein
the gate and the drain of the second transistor are electrically coupled to a gate of the first transistor.

4. The semiconductor memory device according to claim 1, wherein
the second conductive layer extends in a second direction, and
a source and the drain of the second transistor are aligned in a third direction intersecting the second direction.

5. The semiconductor memory device according to claim 4, further comprising:
a third conductive layer extending in the third direction and coupled to the second conductive layer,
wherein the gate and the drain of the second transistor are coupled to the third conductive layer.

6. The semiconductor memory device according to claim 1, wherein
the second conductive layer extends in a second direction, and
the semiconductor memory device further comprises:
a third conductive layer extending in a third direction intersecting the second direction, the third conductive layer being coupled to the first transistor; and
a fourth conductive layer below the second conductive layer and the third conductive layer, the fourth conductive layer being coupled to the second conductive layer and the third conductive layer and extending in the third direction, and
the gate and the drain of the second transistor are coupled to the fourth conductive layer.

7. The semiconductor memory device according to claim 6, wherein
the second conductive layer and the third conductive layer are located at the same position with respect to the first direction.

8. The semiconductor memory device according to claim 1, further comprising:
a third conductive layer below the second conductive layer and coupled to the second conductive layer,
wherein p×q transistors are aligned in a region of the second region below a region through which the number i at most of conductive layers pass, to form p rows and q columns at the same position as the third conductive layer in the first direction, where i is an integer equal to or greater than 1, and where p and q are integers that satisfy p×q being equal to or greater than i.

9. The semiconductor memory device according to claim 1, wherein
the second region is adjacent to the first region.

10. The semiconductor memory device according to claim 1, further comprising:
a first semiconductor layer extending in the first direction in the plurality of first conductive layers; and
an insulating film between the first semiconductor layer and the first conductive layers.

11. A semiconductor memory device comprising:
a plurality of first conductive layers aligned in a first direction with a space in between;
a plug arrangement portion below the first conductive layers, the plug arrangement portion being provided with a first plug extending upward above the first conductive layers; and
an antenna element arrangement portion below the first conductive layers and adjacent to the plug arrangement portion, the antenna element arrangement portion being provided with an antenna element being electrically coupled to an interconnect between the first plug and a transistor.

12. The semiconductor memory device according to claim 11, wherein
the antenna element arrangement portion is provided between the plug arrangement portion and the transistor.

13. The semiconductor memory device according to claim 11, wherein
the antenna element has a drain and a gate, the drain and the gate of the antenna element is electrically coupled to a gate of the transistor via the interconnect.

14. The semiconductor memory device according to claim 11, wherein
the transistor is electrically coupled to the first plug via the interconnect.

15. A semiconductor memory device comprising:
a memory cell array;
a plug arrangement portion below the memory cell array, the plug arrangement portion being provided with a first plug electrically coupled to a first interconnect above the memory cell array;
a peripheral circuit portion below the memory cell array, the peripheral circuit portion being provided with a first transistor; and
an antenna element arrangement portion between the plug arrangement portion and the peripheral circuit portion, the antenna element arrangement portion being provided with an antenna element electrically coupled to a second interconnect between the first plug and the first transistor.

16. The semiconductor memory device according to claim 15, wherein
the antenna element has a drain and a gate,
the drain and the gate of the antenna element is electrically connected a gate of the first transistor via the second interconnect.

17. The semiconductor memory device according to claim 15, wherein
The first plug penetrates the memory cell array.

18. The semiconductor memory device according to claim 15, wherein
the first transistor is electrically coupled to the first plug via the second interconnect.
